(19) United States
(12) Patent Application Publication
(10) Pub. No.: US 2005/0148127 A1
(43) Pub. Date: Jul. 7, 2005

(54) Semiconductor device including gate dielectric layer formed of high dielectric alloy and method of fabricating the same

(75) Inventors: Hyung-Suk Jung, Suwon-si (KR); Jong-Ho Lee, Suwon-si (KR); Seok-Joo Doh, Suwon-si (KR); Yun-Seok Kim, Seoul (KR)

Correspondence Address: Anthony P. Onello, Jr.;MILLS & ONELLO LLP, Suite 605, Eleven Beacon Street, Boston, MA, 02108, US

(73) Assignee: Samsung Electronics Co., Ltd.

(21) Appl. No.: 10/989,200

(22) Filed: Nov. 15, 2004

(30) Foreign Application Priority Data
Dec. 22, 2003 (KR) 03-94813

(51) Int. Cl. H01L 21/336

(52) U.S. Cl. 438/197

(57) ABSTRACT

A semiconductor device is disclosed comprising an improved gate dielectric layer formed of a high dielectric alloy-like composite together with a method for fabricating the same. The semiconductor device comprises a semiconductor substrate and a gate dielectric layer consisting essentially of a high-k alloy-like composite containing a first element, a second element, and oxygen (O). The first element is at least one member selected from a first group consisting of Al, La, Y, Ga, and In. The second element is at least one member selected from a second group consisting of Hf, Zr, and Ti. A diffusion barrier is formed on the gate dielectric layer, and a gate is formed on the diffusion barrier.

### CROSS-REFERENCE TO RELATED APPLICATION

This application claims the benefit of Korean Patent Application No. 2003-94813, filed on Dec. 22, 2003, the disclosure of which is hereby incorporated herein by reference in its entirety.

### BACKGROUND OF THE INVENTION

1. Field of the Invention

The present invention relates to a method for fabricating a semiconductor device and, more particularly, to a semiconductor device including a gate dielectric layer formed of a high dielectric alloy and method of fabricating the same.

2. State of the Art

As semiconductor devices have become more highly integrated and of increased capacity, a gate length of a metal oxide semiconductor field effect transistor (MOSFET) has been shortened and also the thickness of the gate dielectric layer has become thinner. A silicon oxide layer (SiO₂) is the most widely used material for the conventional gate dielectric layer. The silicon oxide layer (SiO₂) not only has superior thermal stability and reliability but can be readily formed.

At the same time, the capacitance between the semiconductor substrate and the gate has been increased, thereby increasing the speed of the semiconductor device. The dielectric constant of a typical silicon oxide layer widely used as the gate dielectric layer is typically only about 3.9, which is not a high value, so that the thickness of the gate dielectric layer would need to be decreased in order to increase the capacitance to the desired value. However, when the thickness of the gate dielectric layer becomes too thin, dielectric breakdown can occur. In addition, excessive leak currents can occur due to a tunneling effect. The level of leak current is a function of the physical thickness of the gate dielectric layer. Alternatively, the gate dielectric layer may be formed of a material having a dielectric constant higher than that of the silicon oxide layer, namely, a high-k dielectric material, while maintaining normal dielectric layer thickness, so that the leak current may be limited to acceptable levels. The reason is that the thickness of a high-k dielectric layer capable of obtaining a given capacitance is thicker than the silicon oxide layer required to obtain the same capacitance.

As such, in response to the movement toward high integration and large capacity semiconductor devices, research has been conducted on using a gate dielectric layer formed of a high-k dielectric material. The high-k gate dielectric layer may be formed of various materials including (Baₓ, Sr₁₋ₓ)TiO₃ (hereinafter referred to as BST), TiO₂, Ta₂O₅, ZrO₂, Zr-silicate, HfO₂, Hf-silicate, Al₂O₃, Y₂O₃, and others. However, it has been found that several problems occur in response to formation of the high-k dielectric layer in semiconductor applications. For example, when BST, TiO₂ or Ta₂O₅ is deposited on a silicon substrate to form the high-k dielectric layer, interface trap density increases due to a reaction between the high-k dielectric layer and the silicon substrate with the undesirable result that carrier mobility decreases. When a thin SiO₂ layer (e.g., about 1 nm thick) is formed as a buffer layer between the high-k dielectric layer and the silicon substrate in order to block the reaction therebetween, equivalent oxide thickness (EOT) is increased thereby inevitably decreasing the capacitance of the resulting gate dielectric layer. In addition, most of the known high-k dielectric layers are subject to crystallization during the conventional thermal treatment process used for activating dopants that have been doped into source/drain regions, with the result that a gate leak current increases and surface roughness also increases thereby degrading the quality of the semiconductor device. Thus, as an example, Al₂O₃ having a high thermal stability among the various high-k dielectric materials may be used as the gate dielectric layer. However, the dielectric constant of Al₂O₃ is about 11, which is not a high value. Furthermore, the Al₂O₃ layer has its flat band shifted to a right direction relative to the flat band of the silicon oxide layer due to negative fixed charges present within the Al₂O₃ layer, so that it is difficult to adjust the threshold voltage for such a semiconductor device. As a result, the research has been conducted to form a satisfactory gate dielectric layer employing ZrO₂ and HfO₂, which materials have a high dielectric constant of 25 to 30 and also have good thermal stability. However, there occurs a problem in that the ZrO₂ reacts with the silicon when only ZrO₂ is used. In addition, when thick HfO₂ is formed, it has a low crystallization temperature so that it is readily crystallized during a deposition process and thereby increases the leak current through a grain boundary. In addition, when only one of ZrO₂ and HfO₂ is used, there is a difficulty in adjusting the threshold voltage because its flat band is shifted to a left direction relative to the flat band of the silicon oxide layer due to positive fixed charges within the ZrO₂ or HfO₂.

To cope with the various problems as discussed above with respect to each of the above-mentioned high-k dielectric layers, this invention describes a method for forming a gate dielectric layer fabricated with at least two kinds of high-k dielectric materials. By way of example, in accordance with the present invention, a laminated gate dielectric composite layer having alloy-like properties may be formed by stacking high-k dielectric layers of Al₂O₃ and HfO₂ or ZrO₂. In addition, also in accordance with the present invention, methods for forming nano-laminated high-k dielectric composite layers also having alloy-like properties employing an atomic layer deposition technique are also disclosed, which allows adjusting their formation and thickness on an atomic layer basis.

3. Description of Related Art

U.S. Pat. No. 6,407,435, entitled “Multilayer Dielectric Stack and Method” by Yangun Ma et al., discloses a multilayered gate dielectric structure including a high-k dielectric layer. Referring to FIG. 1 of the present invention, which is used to illustrate the method disclosed in U.S. Pat. No. 6,407,435, the Figure illustrates preparing a semiconductor substrate 10 having an active area 10a and a device isolating region 10b. A multilayered gate dielectric layer 11 consisting of alternating layers of Al₂O₃ and ZrO₂, namely ZrO₂ (11a)/Al₂O₃ (11b)/ZrO₂ (11c)/Al₂O₃ (11d)/ZrO₂ (11e)/Al₂O₃ (11f), is formed on the semiconductor substrate 10. A gate 12 is then formed on the surface of the last deposited layer 11f of the gate dielectric layer 11.

It is also important that the gate dielectric layer should prevent impurities within a polysilicon layer forming the gate from diffusing into the substrate. In particular, boron within the polysilicon layer forming the gate of a p-type metal oxide semiconductor field effect transistor (pMOSFET) should be effectively prevented from diffusing into the substrate. When the gate dielectric layer is formed of a high-k constant dielectric layer, it may be formed to have a thickness thicker than that of a silicon oxide dielectric layer, however, as previously discussed, the high-k dielectric materials also tend to be readily crystallized so that boron in the polysilicon layer forming the gate is more easily diffused through a grain boundary and into the substrate.

For example, in the prior art semiconductor device as shown in FIG. 1 of this application, when the gate 12 is formed of a polysilicon layer doped with boron, and Al₂O₃ layer 11f of the gate dielectric layer 11 is in contact with the gate 12 as illustrated in FIG. 1, it is difficult to prevent boron from diffusing through the several alternating layers of Al₂O₃ and ZrO₂ which comprise dielectric layer 11, and then into the semiconductor substrate, which causes a serious deterioration in the performance characteristics of the semiconductor device. These and other problems with and limitations of the prior art are addressed in whole or in part by the semiconductor devices and methods of this invention.

### SUMMARY OF THE INVENTION

It is, therefore, a general objective of the present invention to provide semiconductor devices comprising an improved gate dielectric layer formed of a high-k dielectric alloy layer and methods for fabricating the same.

According to one embodiment of the present invention, the semiconductor devices of this invention comprise a semiconductor substrate and a gate dielectric layer having improved performance characteristics formed on the semiconductor substrate. The gate dielectric layer according to the present invention consists generally of an alloy-like composite consisting essentially of a first element and a second element, each of these elements being combined with oxygen (O). The first element of the gate dielectric layer is at least one member of a first group consisting of Al, La, Y, Ga, and In. The second element is at least one member of a second group consisting of Hf, Zr, and Ti. Another feature of this invention is the step of forming a diffusion barrier on the gate dielectric layer. A gate is thereafter formed on the diffusion barrier.

According to another embodiment of the present invention, the semiconductor device of this invention comprises a semiconductor substrate including a first region in which an nMOS transistor is formed and a second region in which a pMOS transistor is formed. First and second gate dielectric layers are formed respectively on the first and second regions of the semiconductor substrate. Each of the first and second gate dielectric layers is formed of an alloy-like composite consisting essentially of a first element and a second element, each of these elements being combined with oxygen (O). The first element of the first and second gate dielectric layers is at least one member of a first group consisting of Al, La, Y, Ga, and In. The second element of the first and second gate dielectric layers is at least one member of a second group consisting of Hf, Zr, and Ti. A diffusion barrier is formed on at least the second gate dielectric layer which is formed on the second (pMOS transistor) region of the substrate. First and second gates are thereafter formed respectively on the first gate dielectric layer and on the diffusion barrier on the second gate dielectric layer.

According to still another embodiment of the present invention, the invention comprises a method for fabricating a semiconductor device including the step of forming a gate dielectric layer having improved performance characteristics on a semiconductor substrate. The gate dielectric layer according to this invention is formed of an alloy-like composite consisting essentially of a first element which is at least one member of a first group consisting of Al, La, Y, Ga, and In, and a second element which is at least one member of a second group consisting of Hf, Zr, and Ti, each of these elements being combined with oxygen (O). In accordance with this embodiment of the invention, a diffusion barrier is formed on the gate dielectric layer. A gate is thereafter formed on the diffusion barrier.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a schematic cross-sectional view illustrating a representative structure of a prior art semiconductor device;

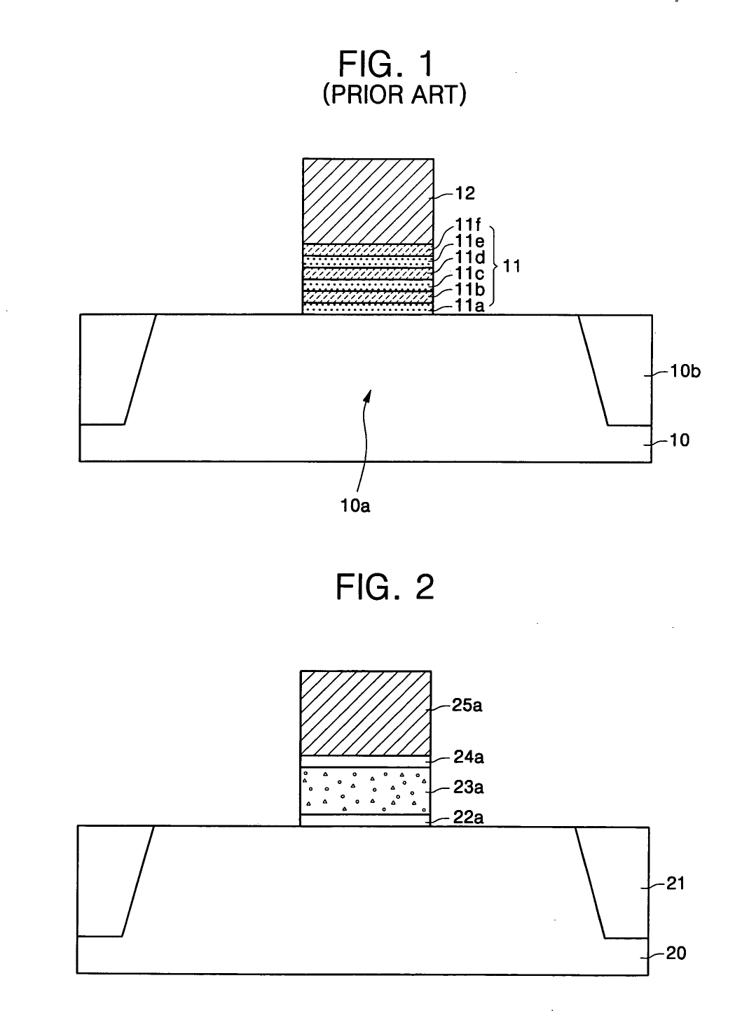

FIG. 2 is a schematic cross-sectional view illustrating a representative structure of a semiconductor device in accordance with one embodiment of the present invention;

FIG. 3 is a schematic cross-sectional view illustrating a representative structure of a semiconductor device in accordance with another embodiment of the present invention;

FIG. 4a and FIG. 4b are schematic cross-sectional views for explaining a method for fabricating a semiconductor device in accordance with an embodiment of the present invention;

FIG. 5 is a process flow chart showing a series of sequential steps for forming a gate dielectric layer of a semiconductor device in accordance with an embodiment of the present invention;

FIG. 6A is a schematic cross-sectional view showing a HfAlO high-k dielectric alloy-like composite layer having a laminated structure;

FIG. 6B is a schematic cross-sectional view showing a HfAlO high-k dielectric alloy-like composite layer with an aluminate-type integral structure;

FIGS. 7A, 7B, and 7C are secondary ion mass spectroscopy (SIMS) profiles for showing the differing degrees of boron diffusion when, respectively, a SiO₂ layer, an Al₂O₃ layer, and a HfO₂ layer are formed between a semiconductor substrate and a gate;

FIGS. 8A to FIG. 8C are timing diagrams illustrating alternative timing/deposition sequences of source supply and purge for forming a HfAlO dielectric alloy-like composite layer in accordance with different embodiments of this invention;

FIG. 9 is a graph showing a threshold voltage change of a transistor as a function of gate length with respect to varying amounts of Al₂O₃ contained in a HfAlO high-k dielectric alloy layer;

FIG. 10 is a graph showing a drain breakdown voltage change with respect to an Al rate;

FIG. 11A is a schematic cross-sectional view showing a semiconductor device according to an embodiment of this invention having a HfO₂ layer as the top layer of a gate dielectric layer in contact with a gate;

FIG. 11B is a schematic cross-sectional view showing a semiconductor device according to an embodiment of this invention having an Al₂O₃ layer as the top layer of a gate dielectric layer in contact with a gate; and

FIG. 12A and FIG. 12B are graphs comparing the C-V characteristics of different transistors.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided for illustration and example so that this disclosure will be thorough and complete, and will fully convey the scope of the invention to those skilled in the art. The accompanying drawings are not to scale; in particular, the thicknesses of layers and regions are exaggerated for clarity. Like numbers refer to like elements throughout the specification even in discussing alternative embodiments of the invention.

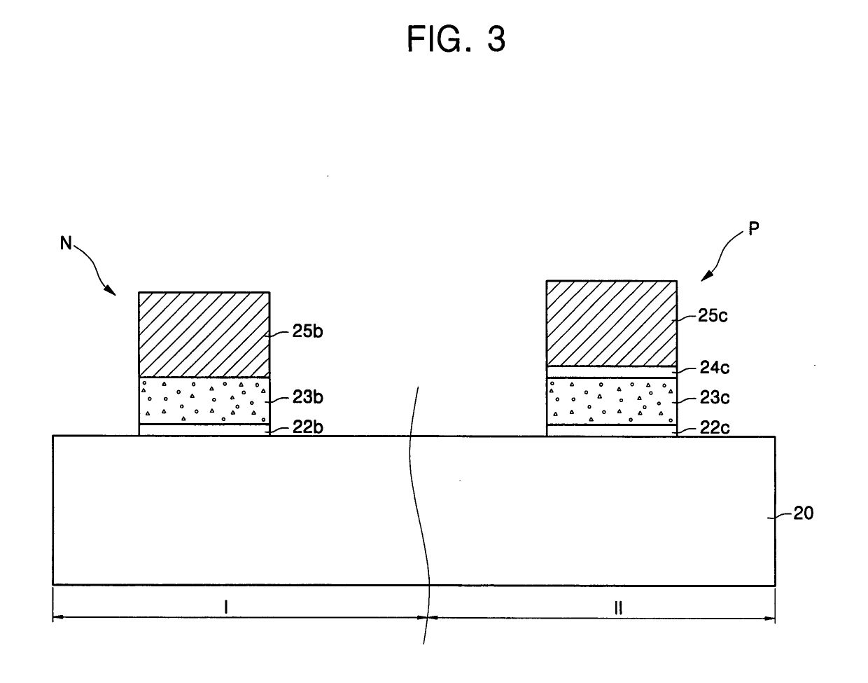

Referring now to FIG. 2, a semiconductor device in accordance with one embodiment of the present invention is shown, which device generally comprises a semiconductor substrate 20, a gate dielectric layer 23a, a diffusion barrier 24a, and a gate 25a, which layers are stacked sequentially on the semiconductor substrate 20. The gate dielectric layer 23a is formed of a high-k dielectric alloy-like composite layer in accordance with this invention. Layer 22a is an optional buffer layer that will be discussed herinafter.

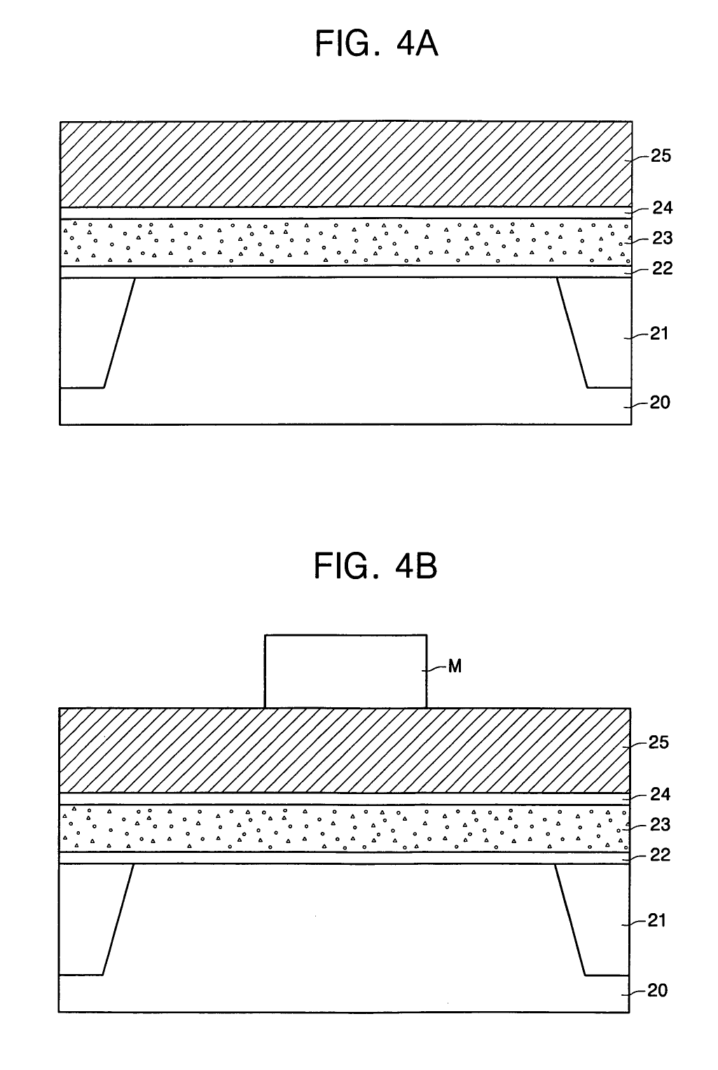

Referring now to FIG. 3, a semiconductor substrate 20 of a semiconductor device in accordance with another embodiment of the present invention may comprise a first region I in which an n-type metal oxide semiconductor field effect transistor (nMOSFET or N for short) is formed, and a second region II in which a p-type metal oxide semiconductor field effect transistor (pMOSFET or P for short) is formed. The nMOSFET (N) may include a gate dielectric layer 23b and a gate 25b, optionally together with a buffer layer 22b, stacked on the first region I of the semiconductor substrate 20. The pMOSFET (P) may include a gate dielectric layer 23c, a diffusion barrier 24c, and a gate 25c, optionally together with a buffer layer 22c, stacked on the second region II of the semiconductor substrate 20.

In the semiconductor device in accordance with the FIG. 3 embodiment of the present invention, the gate 25b of the nMOSFET (N) is in contact with the gate dielectric layer 23b, and the gate 25c of the pMOSFET (P) is in contact with the diffusion barrier 24c. These gate dielectric layers 23b and 23c are formed of a high-k dielectric alloy-like composite in accordance with the invention.

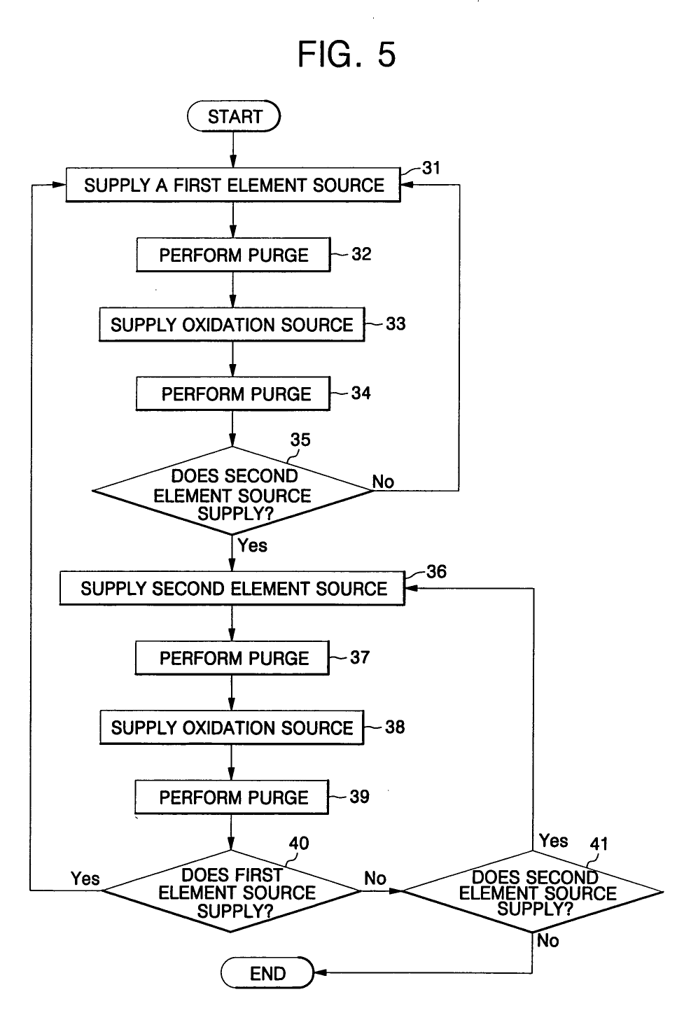

The semiconductor substrate 20 may be a silicon substrate. The semiconductor substrate 20 may include a device isolating layer 21 (not shown in FIG. 3 but illustrated in FIGS. 4A and 4B) formed in the substrate. The gate dielectric layers 23a, 23b, and 23c of FIGS. 2 and 3 are formed of a high-k dielectric alloy-like composite which is a composite consisting essentially of a first element, which is at least one member of a first group consisting of Al, La, Y, Ga, and In, a second element, which is at least one member of a second group consisting of Hf, Zr, and Ti, and oxygen (O). In some embodiments of the invention, the composite may further contain nitrogen N. The number of monolayers of the second element of the composite in gate dielectric layers 23a, 23b, and 23c may be the same as or preferably more than that of the first element. The thickness of the gate dielectric layers 23a, 23b, and 23c may typically be from about 40 A° to about 60 A°. The gate dielectric layers 23a, 23b, and 23c may comprise a HfAlO layer, which is formed to be stacked with a mono molecular layer of HfO₂ and a mono molecular layer of Al₂O₃.

The diffusion barrier 24c may be formed of at least one material selected from the group consisting of a SiO₂ layer, a HfO₂ layer, a ZrO₂ layer, a silicate oxide layer, a SiON layer, a HfON layer, a ZrON layer, and a silicate oxynitride layer. The silicate oxide layer may generally be represented by the chemical formula M₁₋ₓSiₓO₂, where x is a positive number up to and including 1, preferably in the range of 0.2 to 0.99. The M may be any one metal element selected from a group consisting of Hf, Zr, Ta, Ti and Al. The silicate oxynitride layer may contain Si, N, O, and at least one element selected from the group consisting of Hf, Zr, Ta, Ti and Al. The thickness of the diffusion barrier 24 may typically be from about 10 A° to about 20 A°.

In addition, buffer layers 22a, 22b, and 22c, respectively, may be further included between the gate dielectric layers 23a, 23b, and 23c and the semiconductor substrate 20. The buffer layers 22a, 22b, and 22c help to prevent or at least to minimize reaction between the gate dielectric layers 23a, 23b, and 23c and the semiconductor substrate 20. Such buffer layers 22a, 22b and 22c may be formed of any one of a SiO₂ layer and a SiON layer. The thickness of the buffer layers 22a, 22b, and 22c may typically be from about 12 A° to about 15 A°. In invention embodiments where the reaction between the gate dielectric layers 23a, 23b, and 23c and the semiconductor substrate 20 is not significant, the buffer layers 22a, 22b, and 22c may be omitted from the semiconductor device.

The gates 25a, 25b, 25c may be formed of polysilicon layers. In particular, boron may be doped into the gate 25c, formed of a polysilicon layer, on the pMOSFET (P) region of the substrate 20 as shown in FIG. 3. In this case, the diffusion barrier 24c acts to prevent the boron doped into the gate 25c of the pMOSFET (P) from diffusing into the semiconductor substrate 20.

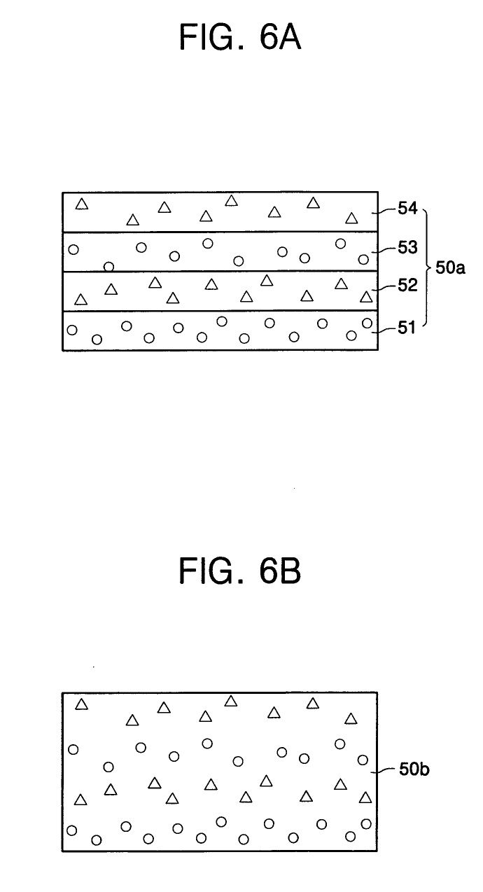

A preferred method for fabricating a semiconductor device in accordance with an embodiment of the present invention will now be described with reference to FIG. 4A, FIG. 4B, FIG. 2, and FIG. 5.

Referring to FIG. 4A, a buffer layer 22, a gate dielectric layer 23, a diffusion barrier 24, and a conductive layer for gate 25 are sequentially stacked on a semiconductor substrate 20 where a device isolating layer 21 is already formed. The gate dielectric layer 23 is formed of a high-k dielectric alloy-like composite in accordance with this invention. The semiconductor substrate 20 may, for example, be a silicon substrate. The buffer layer 22 acts to prevent reaction between the gate dielectric layer 23 and the semiconductor substrate 20. In embodiments where the reaction between the gate dielectric layer and the substrate is not significant, the buffer layer 22 may be omitted. In accordance with the present invention, the buffer layer 22, if present, may be formed of a SiO₂ or SiON layer having a thickness of about 12 A° to about 15 A°.

In a preferred embodiment of the invention, the gate dielectric layer 23 may be formed using an atomic layer deposition method. The semiconductor substrate 20, having a buffer layer 22 already formed (if desired), is transferred into a reaction chamber, and the gate dielectric layer 23 may be then deposited according to the following procedure. Referring to FIG. 5, a first element deposition source (namely, a first element source), containing at least one first element selected from a first group consisting of Al, La, Y, Ga, and In, is supplied into the reaction chamber (step 31) for a controlled period of time and under suitable temperature and pressure conditions so as to deposit a layer of the first element on the substrate, which time and conditions will be apparent to one of ordinary skill in this art. Purge is then performed by supplying an inert gas into the reaction chamber (step 32). Ar or N₂ may be used as the inert gas for this process step. An oxidation source is then supplied into the reaction chamber (step 33) for a controlled period of time and under suitable temperature and pressure conditions so as to form an oxide of said first element, which time and conditions will be apparent to one of ordinary skill in this art. H₂O gas may be used as the oxidation source. A purge step is again performed by again supplying an inert gas into the reaction chamber (step 34). In accordance with the steps of alternately supplying the first element source and oxidation source, and performing the purge, a first molecular layer of a desired thickness containing the first element and oxygen may be obtained. The first molecular layer is preferably formed to be thinner than about 5 A°. Such sequential process is repeated until it is determined (step 35) that it is time for a second element deposition source (namely, a second element source), containing at least one second element, to be supplied to the reaction chamber. When the second element source is not supplied, in other words, when the first molecular layer is further formed, the sequential steps of supplying the first element source (step 31), performing the purge (step 32), supplying the oxidation source (step 33), and performing the purge (step 34) may be repeated at least once. When the second element source is supplied, a deposition source for at least one second element, selected from a second group consisting of Hf, Zr, and Ti, is supplied into the reaction chamber (step 36) for a controlled period of time and under suitable temperature and pressure conditions so as to deposit a layer of the second element on the first formed layer, which time and conditions will be apparent to one of ordinary skill in this art. An inert gas is then supplied into the reaction chamber to perform a purge (step 37). An oxidation source is then supplied into the reaction chamber (step 38) for a controlled period of time and under suitable temperature and pressure conditions so as to form an oxide of said second element, which time and conditions will be apparent to one of ordinary skill in this art. Inert gas is then again supplied into the reaction chamber to perform another purge (step 39). In accordance with the steps of alternately supplying the second element source and oxidation source, and performing the purge, a second molecular layer of a desired thickness containing the second element and oxygen may be obtained. The second molecular layer is preferably formed to be thinner than about 5 A°. Because the first and second molecular layers are formed in accordance with the above-mentioned procedure, a gate dielectric layer formed of a high-k dielectric alloy-like composite containing the first element, second element, and oxygen may be obtained. It is then determined whether another deposition cycle in the process for forming the gate dielectric layer is to be performed or not. For example, it is determined whether the first element source is to be supplied (step 40). In accordance with an embodiment of the present invention, when it is desired that the gate dielectric layer 23 be formed to be about 40 A° to about 60 A° in thickness, the sequential steps of supplying the first element source (step 31), performing the purge (step 32), supplying the oxidation source (step 33), and again performing the purge (step 34), in the process of forming the first molecular layer may be repeated at least once. In addition, when the first element source is not to be further supplied, it is determined whether the second element source is to be supplied or not (step 41). The sequential steps of supplying the second element source (step 36), performing the purge (step 37), supplying the oxidation source (step 38), and again performing the purge (step 39), in the process of forming the second molecular layer may be repeated at least once. In a preferred embodiment of this invention, the number of monolayers of the second element within the gate dielectric layer 23 is preferably more than that of the first element in order to prevent the permittivity of the layer from being lowered. To that end, the steps of forming the second molecular layer may be repeated more times than the steps of forming the first molecular layer.

Nitrogen, such as in the form of nitride, may be further contained in the gate dielectric layer 23. When a nitrogen (nitride) source is supplied to the reaction chamber, and purge is performed as in the above-mentioned steps 32, 34, 37, and 39, a gate dielectric layer 23 is formed of a high-k dielectric alloy-like composite containing the first element, the second element, oxygen, and nitrogen (nitride).

In the above-described embodiments of the present invention, the elements selected from the first and second groups are referred to as the first element and the second element, respectively. However, in some embodiments of the invention, the first element may also be an element selected from the second group consisting of Hf, Zr, and Ti, and, correspondingly, the second element may also be an element selected from the first group consisting of Al, La, Y, Ga, and In. In other words, the first element source and the second element source may be supplied to the reaction chamber in the reverse order of that shown in FIG. 5. In this case, the number of monolayers of the first element within the gate dielectric layer 23 would preferably be more than the number for the second element. To that end, the sequence of steps for forming the first molecular layer may be repeated more than in forming the second molecular layer.

Hereinafter, a method for forming a HfAlO layer as the gate dielectric layer 23 for a semiconductor device will be described in accordance with another embodiment of the present invention.

First, HfCl₄ gas as a deposition source of the first element Hf is supplied into the reaction chamber (corresponding to step 31 of FIG. 5) and purge is then performed in the same chamber (corresponding to step 32 of FIG. 5). H₂O gas as an oxidation source is then supplied into the reaction chamber (corresponding to step 33 of FIG. 5) and thereafter the purge is again performed (corresponding to step 34 of FIG. 5). As a result of this sequence of steps, a mono molecular layer of HfO₂ is deposited on the surface of the substrate. The sequential steps of supplying the HfCl₄ gas, performing the purge, supplying the H₂O gas, and again performing the purge will be performed at least once and the cycle may be repeated two or more times. Trimethylaluminum (TMA) or dimethyl aluminum hydride (DMAH) as a deposition source of Al is thereafter supplied into the reaction chamber (corresponding to step 36 of FIG. 5) and the purge is then performed (corresponding to step 37 of FIG. 5). H₂O gas as an oxidation source is then supplied into the reaction chamber (corresponding to step 38 of FIG. 5) and purge is again performed (corresponding to step 39 of FIG. 5). As a result, a mono molecular layer of Al₂O₃ is deposited on the previously formed layer of HfO₂. As a result, a HfAlO high-k dielectric alloy-like composite (formed of HfO₂ and Al₂O₃) is obtained by depositing the HfO₂ and Al₂O₃ on a molecular layer basis. Since the dielectric constant of Al₂O₃ by itself is not high, it is preferable to have the amount of Hf in the HfAlO layer be greater than the amount of Al in the HfAlO layer. Thus, a high-k dielectric alloy-like composite layer of HfAlO may be formed in which more of the HfO₂ molecular layer is deposited than of the Al₂O₃ molecular layer.

The diffusion barrier 24 may be formed of at least one material selected from the group consisting of a SiO₂ layer, a HfO₂ layer, a ZrO₂ layer, a silicate oxide layer having the general chemical formula (M₁₋ₓSiₓO₂), a SiON layer, a HfON layer, a ZrON layer, and a silicate oxynitride layer. The term ‘M’ of the chemical formula for the silicate oxide layer may be any one metal element selected from the group consisting of Hf, Zr, Ta, Ti, and Al; and the composition rate ‘x’ of the chemical formula may preferably be between about 0.2 to 0.99. The silicate oxide layer may be formed using an atomic layer deposition method. In this case, the silicate oxide layer may be formed by repeatedly performing the sequence of steps of alternately supplying the metal M, silicon, and oxidation sources, and performing intervening purge steps. In this case, ZrCl₄ or HfCl₄ may be supplied as the metal source. SiH₄ or SiCl₄H₂ may be supplied as the silicon source. H₂O may be supplied as the oxidation source. In another variation of this embodiment, an additional nitrogen (nitride) source may be supplied to form a silicate oxynitride layer. NH₃ may be supplied as the nitrogen source for this embodiment. The silicate oxide diffusion barrier layer may also be formed using a metal organic chemical vapor deposition (MOCVD) method as is generally known in the art. The deposition for the silicate oxide layer using the MOCVD method may be performed using a precursor such as Hf(O—Si—R₃)₄ or Zr(O—Si—R₃)₄. In these chemical equations, R typically represents C₂H₅. In addition, Hf-t-butoxide may be used as the Hf source, and Zr-t-butoxide may be used as the Zr source for this embodiment. In addition, tetra-ethoxy-ortho-silane or tetra-ethyl-ortho-silicate may be used as the silicon source. In still another embodiment, the silicate oxide layer may be formed using a reactive sputtering method as is generally known in the art.

The conductive layer 25 of the gate may be formed of a polysilicon layer. Boron may be doped into the polysilicon layer. In this case, the diffusion barrier 24 may act to prevent or minimize the boron that was doped into the conductive layer 25 that forms the gate from diffusing into the semiconductor substrate 20 resulting in adversely affecting the performance characteristics of the semiconductor device.

Referring again to FIG. 4B, an etch mask M may be formed on the conductive layer 25. The conductive layer 25, the diffusion barrier 24, the gate dielectric layer 23, and the buffer layer 22 are then patterned to obtain the patterned gate 25a, diffusion barrier 24a, gate dielectric layer 23a, and buffer layer 22a as shown in FIG. 2. The etch mask M is then removed.

### EXAMPLE 1

Performance characteristics with respect to the structure of a HfAlO dielectric layer prepared according to the present invention were observed in the present example.

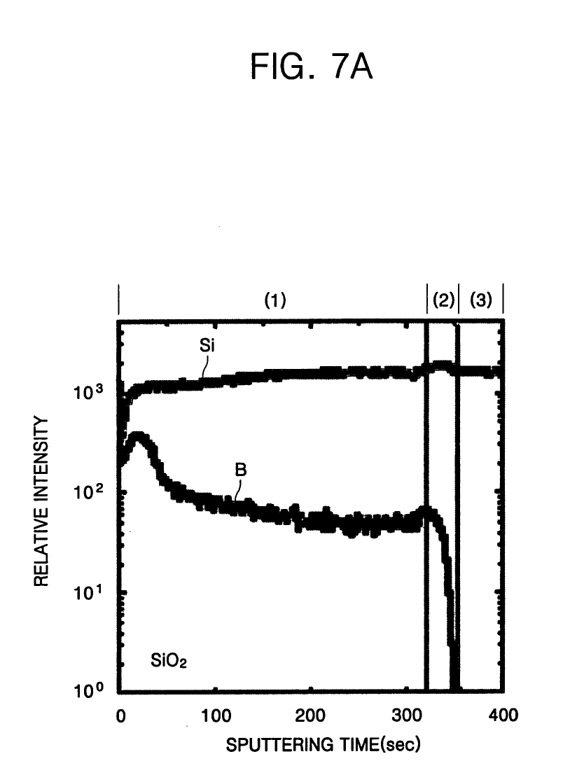

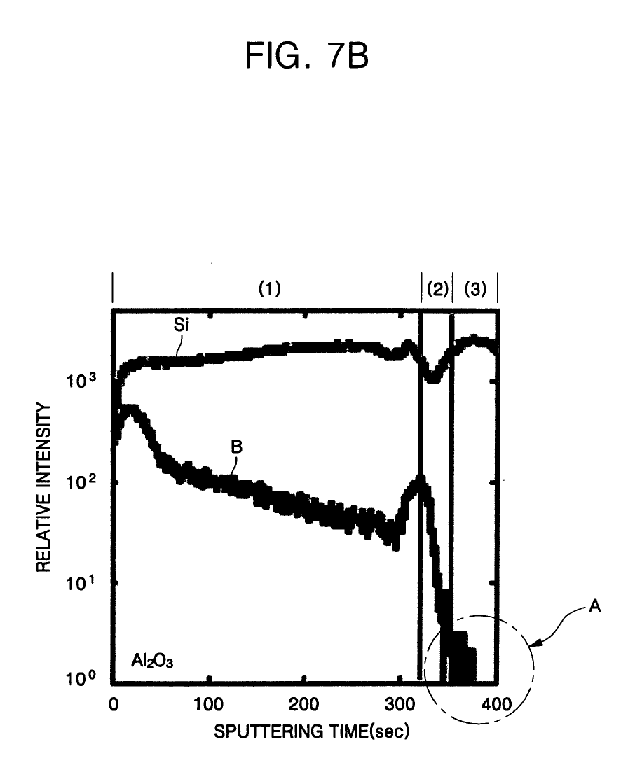

As shown in FIG. 6A, a HfAlO layer 50a may be formed having a laminated structure such that HfO₂ layers 51 and 53 (represented by circles) and Al₂O₃ layers 52 and 54 (represented by triangles) are alternately stacked layer by layer. The boundary between the HfO₂ layers 51 and 53 and the Al₂O₃ layers 52 and 54 may be discriminated using a transmission electron microscope (TEM). The HfAlO layer 50a having the laminated structure could be obtained by repeatedly depositing the HfO₂ layers 51 and 53 up to a thickness of not less than 5 A° and by repeatedly depositing the Al₂O₃ layers 52 and 54 also up to a thickness of not less than 5 A° by means of the atomic layer deposition method. In this case, the HfO₂ layer and the Al₂O₃ layer may alternatively be formed in the reverse order on the substrate.

FIG. 6B shows an alternative embodiment whererin a HfAlO high-k dielectric alloy-like composite layer 50b having an aluminate-type integral structure of a HfO₂ layer and an Al₂O₃ layer, which are stacked on a molecular basis and having a total thickness of less than 5 A° by means of an atomic layer deposition method. In the dielectric alloy-like integral composite structure of FIG. 6B, a boundary between a HfO₂ layer and an Al₂O₃ layer can not be discriminated by TEM analysis, which is why this embodiment is characterized as an integral structure.

Table 1 below compares the current characteristics of nMOSFETs and pMOSFETs having a HfAlO high-k dielectric layer of the laminated structure shown in FIG. 6A with the HfAlO high-k dielectric alloy-like integral composite layer of the aluminate-type structure shown in FIG. 6B as the gate dielectric layer. Each transistor has a gate dielectric layer having a thickness of 50 A°. When 1.2V was applied to a gate of each transistor having the same off-current characteristic of 10 nA, the on-current characteristics obtained are shown below in Table 1.

TABLE 1

| | Laminated-HfAlO layer | Aluminate-HfAlO layer |
|---|---|---|
| nMOS | 260 μA/μm | 430 μA/μm |
| pMOS | 160 μA/μm | |

As shown in Table 1, the on-current characteristic in the case of the nMOS transistor having the HfAlO high-k dielectric alloy-like integral composite layer of the aluminate-type structure was shown to be superior to the transistor having the HfAlO layer of laminated structure. In the case of the pMOS transistor, however, because of an abnormal operation, it was not possible to measure the on-current for the aluminate-type structure. Such a result was not unexpected, however, because an abnormal operation of the transistor would be expected when boron within the polysilicon gate of the pMOS transistor diffused into the semiconductor substrate. In other words, it was expected that the pMOS transistor having the HfAlO high-k dielectric alloy-like integral composite layer of the aluminate-type structure would tend to allow boron to be more readily diffused into the substrate compared to the pMOS transistor having the HfAlO layer of the laminated-type structure.

As a result, the HfAO high-k dielectric alloy-like integral composite layer of the aluminate-type structure was used as the gate dielectric layer in the case of the nMOS transistor, so that the transistor characteristic of the nMOS transistor could be enhanced. In contrast, in the case of the pMOS transistor having the HfAlO high-k dielectric alloy-like integral composite layer of the aluminate-type structure as the gate dielectric layer, the problem of diffusion of the boron within the polysilicon gate into the semiconductor substrate needed to be overcome. When a diffusion barrier was formed on the HfAlO gate dielectric layer of the pMOS transistor in accordance with an above-described embodiment of the present invention, it was found that the above-mentioned boron diffusion could be effectively suppressed.

### EXAMPLE 2

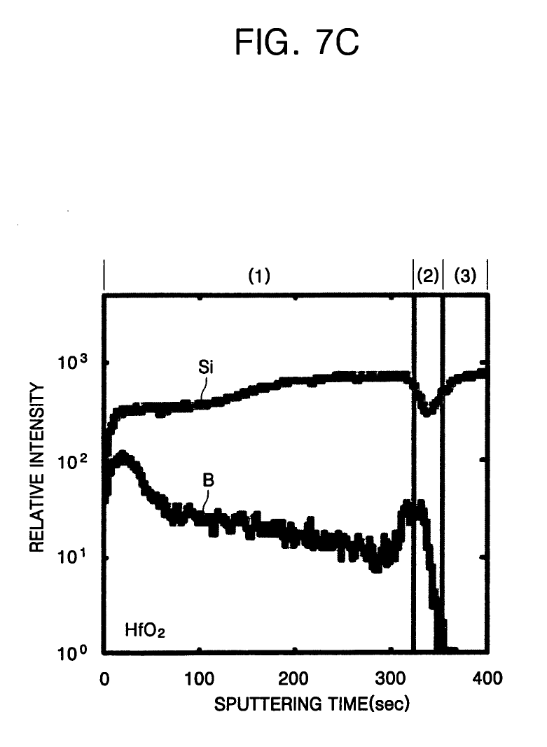

In order to observe a change in the amount of boron diffusion based on the type of a gate dielectric layer, three gate dielectric layers, one of HfO₂, one of Al₂O₃, and one using SiO₂ as the gate dielectric layer, were formed on p-type silicon substrates, and a polysilicon gate doped with boron was formed on each of the gate dielectric layers. Each gate dielectric layer was formed to be the same 30 A° in thickness. Each polysilicon gate was formed to have a thickness of 1500 A°. After boron was implanted into the polysilicon gate and was activated by heating for about 10 seconds at a temperature of about 1000° C., results were measured using secondary ion mass spectrometry (SIMS) analysis. These results are shown in the graphs of FIG. 7A to FIG. 7C. FIG. 7A, FIG. 7B, and FIG. 7C are SIMS profiles showing the degrees of boron diffusion when the SiO₂ layer, Al₂O₃ layer, and HfO₂ layer were formed as the gate dielectric layer, respectively. Regions (1), (2), and (3) of the graphs of FIG. 7A to FIG. 7C each represent, respectively, a polysilicon gate region, a gate dielectric layer region, and a semiconductor substrate region of the semiconductor device. FIGS. 7A and 7C show that when an SiO₂ layer or HfO₂ layer was formed between the semiconductor substrate and the polysilicon layer, boron did not diffuse into the semiconductor substrate region (3). In contrast, FIG. 7B shows that when an Al₂O₃ layer was formed between the semiconductor substrate and the polysilicon layer, a significant amount of boron was diffused up to the semiconductor substrate region (3). In accordance with the present invention, by forming a semiconductor device with a diffusion barrier, such as an SiO₂ or HfO₂ layer, boron diffusion would be expected to be effectively prevented.

### EXAMPLE 3

When a HfAlO layer of the aluminate-type structure was formed by the atomic layer deposition method, a boron diffusion change was observed in response to supplying varying amounts of one source material forming Al₂O₃ and of another source material forming HfO₂.

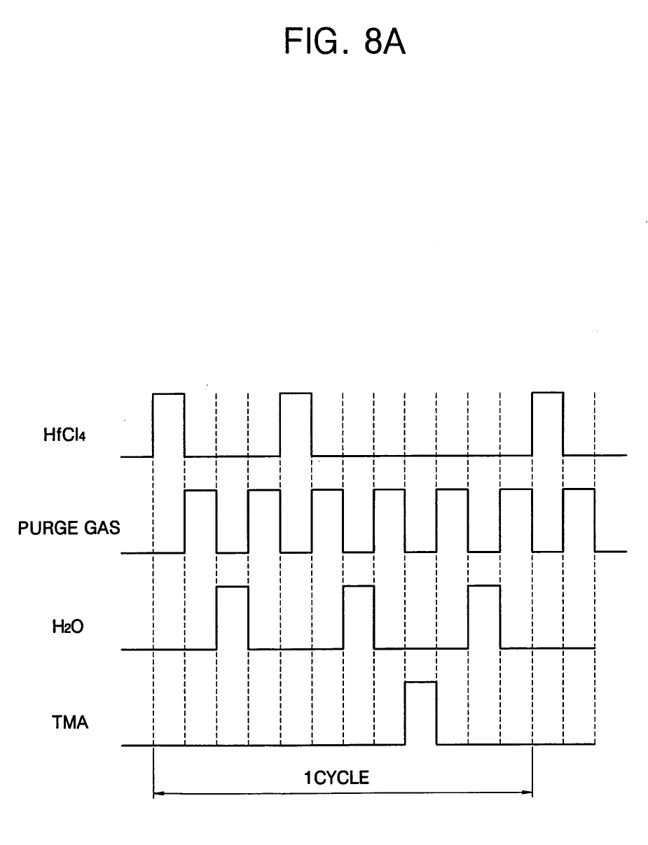

As shown in FIG. 8A to FIG. 8C, an Al source material supply rate was changed in accordance with several conditions. The Al source material supply rate represents a rate of Al with respect to the total amount of Hf and Al, which is a percentage amount based on the fraction Al/(Hf+Al).

As shown in FIG. 8A, HfCl₄ and H₂O as the source materials for the formation of HfO₂ were supplied twice (i.e., two complete deposition cycles), while TMA and H₂O as the source materials for the formation of Al₂O₃ were supplied only once (i.e., one complete deposition cycle). As a result, the Al supply rate was calculated as 32.4%. As shown in FIG. 8B, HfCl₄ and H₂O were supplied four times (four complete deposition cycles), while TMA and H₂O were supplied only once, for an Al supply rate of 14.6%. In the example shown in FIG. 8C, HfCl₄ and H₂O were supplied six times (six complete deposition cycles), while TMA and H₂O were supplied only once, for an Al supply rate of 8.7%.

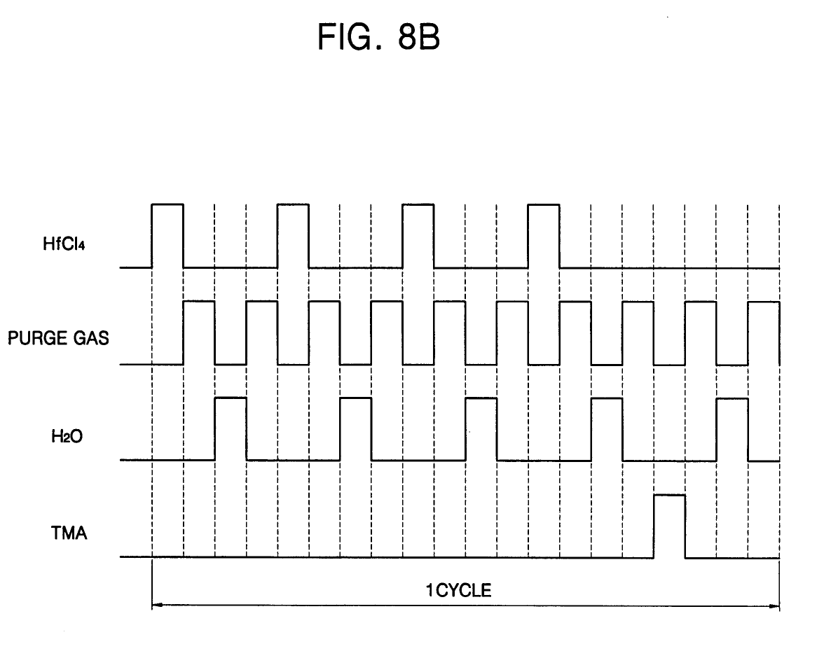

FIG. 9 is a graph showing a change in the threshold voltage of a transistor in response to the amount of Al₂O₃ used to form a HfAlO high-k dielectric alloy-like composite layer. In FIG. 9, the symbols -▪-, -●-, and -▴- represent the threshold voltage change of an nMOS transistor, and the symbols -□-, -◯-, and -Δ- represent the threshold voltage change of a pMOS transistor. The threshold voltage change was not significantly changed in response to the Al supply rate in the case of the nMOS transistor, but it was significantly changed in the case of the pMOS transistor. It was expected that the threshold voltage would be significantly changed due to boron diffusion in the case of the pMOS transistor.

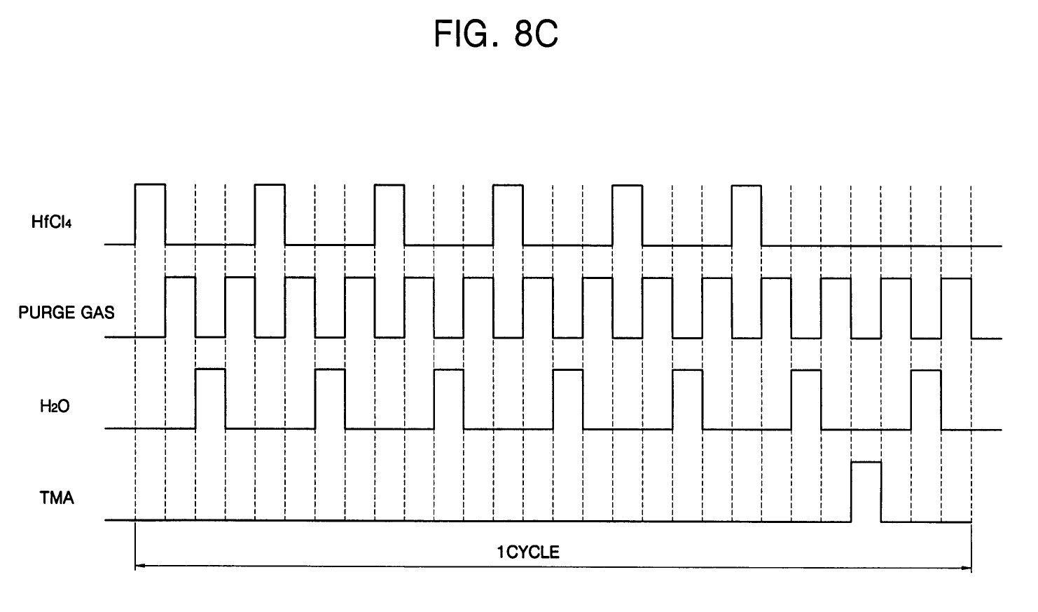

FIG. 10 is a graph showing a change in the drain breakdown voltage in response to a change in the Al supply rate of each transistor having the same off-current characteristic of 10 nA. The breakdown voltage of the nMOS transistor was constant irrespective of the Al supply rate, while that of the pMOS transistor significantly changed in response to a change in the Al supply rate. It was expected in the case of the pMOS transistor that the breakdown voltage would experience a significant change due to the increased amount of boron expected to diffuse into the semiconductor substrate from the polysilicon gate when the Al supply rate increased. As such, when a HfAlO layer was formed in the case of the pMOS transistor, it would be expected that boron would more readily be diffused when the proportion of Al₂O₃ in the alloy-like composite, was increased by increasing the Al supply rate. In accordance with the above-mentioned embodiment of the present invention, it is generally preferred that the amount of Hf be greater than that of the Al within the HfAlO layer, so that boron diffusion is reduced.

### EXAMPLE 4

Boron diffusion effects were observed in response to the addition or selection of a top layer to a gate dielectric layer interposed between a semiconductor substrate and a polysilicon gate. To illustrate these effects, a first nMOS transistor and a first pMOS transistor were formed in which polysilicon gates were placed in contact with top HfO₂ layers on the respective gate dielectric layers. Similarly, a second nMOS transistor and a second pMOS transistor were formed in which polysilicon gates were placed in contact with top Al₂O₃ layers on the respective gate dielectric layers.

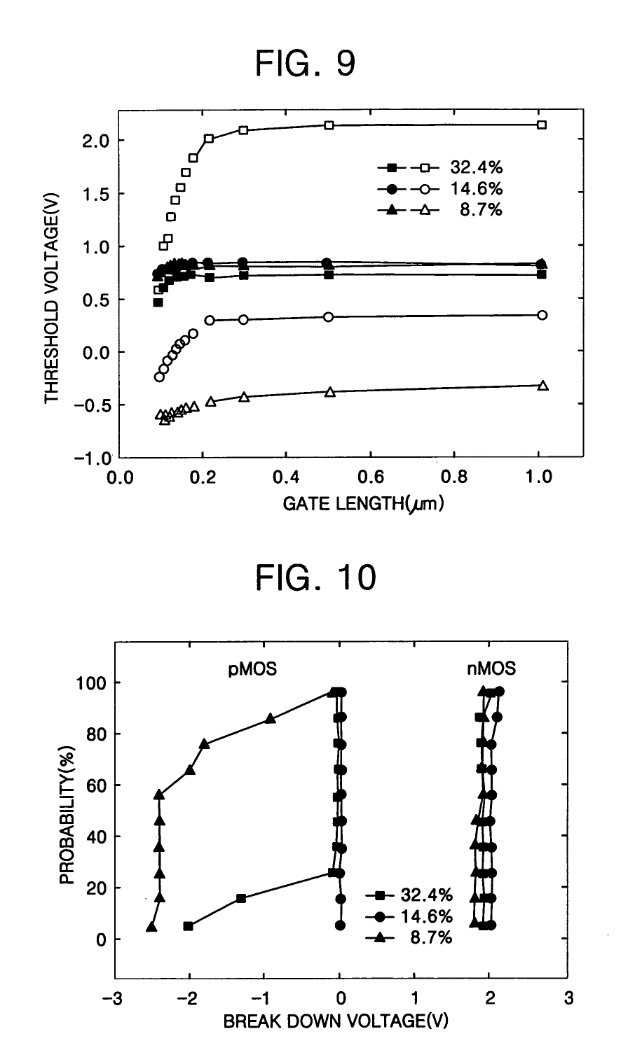

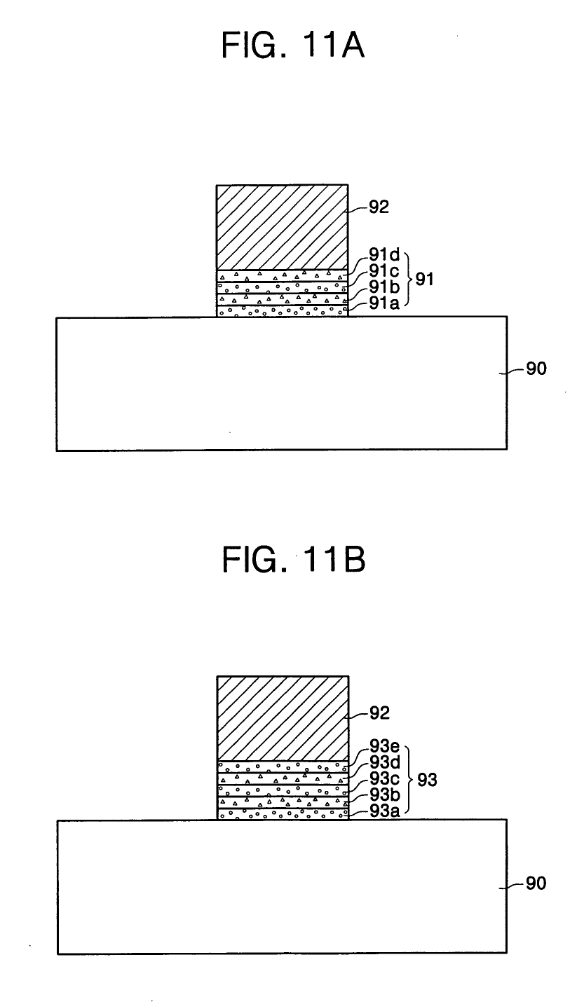

FIG. 11A shows the structure of the first nMOS transistor. The first pMOS transistor had the same structure as the first nMOS transistor except for having a conductive type opposite to that of the first nMOS transistor, so that it was not shown in FIG. 11A. The first nMOS transistor (or the first pMOS transistor) comprised a first gate dielectric layer 91 consisting of an Al₂O₃ layer 91a, a HfO₂ layer 91b, an Al₂O₃ layer 91c, and a HfO₂ top layer 91d between a silicon substrate 90 and a polysilicon gate 92. Each thickness of the Al₂O₃ layers 91a and 91c was 5 A° and each thickness of the HfO₂ layers 91b and 91d was 10 A°.

FIG. 11B shows the structure of the second nMOS transistor. The second pMOS transistor had the same structure as the second nMOS transistor except for having a conductive type opposite to that of the second nMOS transistor, so that it was not shown in FIG. 11B. The second nMOS transistor (or the second pMOS transistor) comprised a second gate dielectric layer 93 consisting of an Al₂O₃ layer 93a, a HfO₂ layer 93b, an Al₂O₃ layer 93c, a HfO₂ layer 93d, and an Al₂O₃ top layer 93e between a silicon substrate 90 and a polysilicon gate 92. Each thickness of the Al₂O₃ layers 93a, 93c, and 93e was 5 A°, and each thickness of the HfO₂ layers 93b and 93d was 10 A°. The second nMOS transistor and the second pMOS transistor were different from the first nMOS transistor and the first pMOS transistor in that they have an additional Al₂O₃ top layer of 5 A° in thickness.

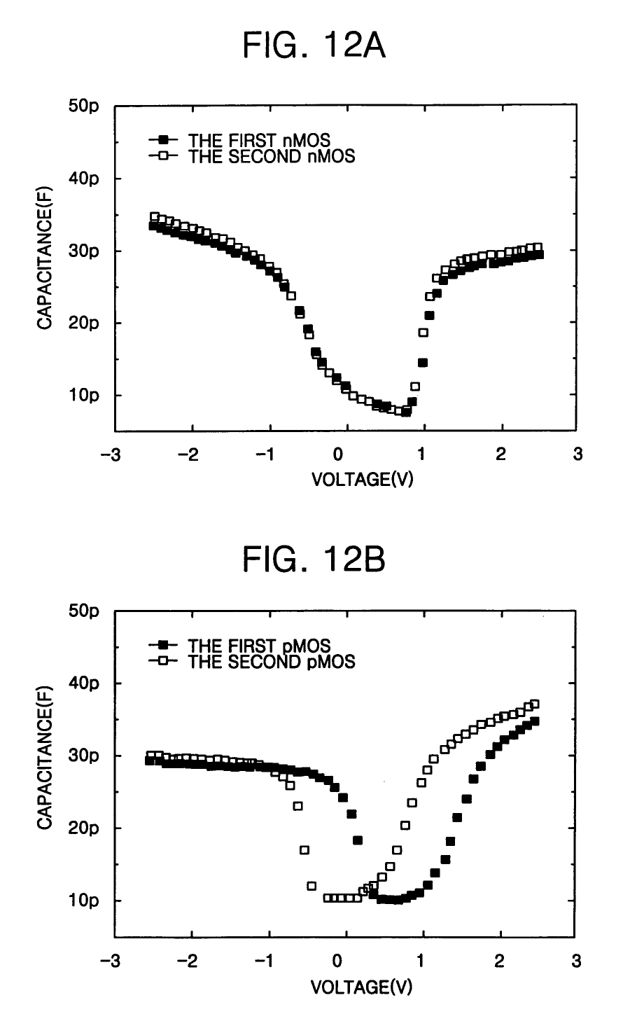

FIG. 12A is a graph comparing C-V characteristics for the first nMOS transistor with the second nMOS transistor, and FIG. 12B is a graph comparing C-V characteristics for the first pMOS transistor with the second pMOS transistor. As shown in FIG. 12A, the C-V characteristics of the nMOS transistors were almost the same regardless of the kind of dielectric layer formed as the top layer of the gate dielectric layers 91 and 93. However, as shown in FIG. 12B, the C-V characteristics of the pMOS transistors were shown to have significant differences based on the kind of dielectric layer formed as the top layer of the gate dielectric layers 91 and 93. In particular, the second pMOS transistor had the additional Al₂O₃ top layer 93e resulting in a gate dielectric layer that was thicker than the first pMOS transistor; however, it was still more apt to allow boron to be diffused when the boron-doped polysilicon gate 92 and the Al₂O₃ layer 93e (that was the top layer of the gate dielectric layer 93) were in contact with each other. As such, it could be seen that boron diffusion depends at least in part on the kind of top gate dielectric layer that is in contact with the polysilicon gate 92. Because the diffusion barrier was formed between the gate of the pMOS transistor and the high-k dielectric alloy-like composite layer in accordance with an embodiment of the present invention, as shown in FIG. 11A, boron diffusion could be effectively prevented by the methods of this invention.

In accordance with the above-mentioned present invention, an improved gate dielectric layer is formed of an alloy consisting essentially of at least two metals and oxygen between a gate and a semiconductor substrate, so that characteristics of a transistor may be enhanced. In addition, a diffusion barrier is formed between the gate dielectric layer and the gate, so that it is possible to prevent boron dopant within the gate from diffusing into the semiconductor substrate.

While the present invention has been described with reference to certain particular embodiments, it is understood that the disclosure has been made for purposes of illustrating the invention by way of examples and not to limit the scope of the invention. One skilled in the art would be able to amend, change, or modify the present invention in many apparent ways without departing from the scope and spirit of the present invention disclosure.

1. A semiconductor device, comprising:
a semiconductor substrate;
a gate dielectric layer formed on the semiconductor substrate of a composite consisting of a first element and a second element, each of these elements being combined with oxygen, the first element being at least one member of a first group consisting of Al, La, Y, Ga, and In, and the second element being at least one member of a second group consisting of Hf, Zr, and Ti;
a diffusion barrier formed on the gate dielectric layer; and
a gate formed on the diffusion barrier.

2. The semiconductor device as claimed in claim 1, wherein the number of layers containing the second element within the gate dielectric layer is greater than the number of layers containing the first element.

3. The semiconductor device as claimed in claim 1, wherein the diffusion barrier consists essentially of at least one material selected from the group consisting of a SiO₂ layer, a HfO₂ layer, a ZrO₂ layer, a silicate oxide layer, a SiON layer, a HfON layer, a ZrON layer, and a silicate oxynitride layer.

4. The semiconductor device as claimed in claim 3, further comprising:
a buffer layer interposed between the semiconductor substrate and the gate dielectric layer, wherein the buffer layer consists essentially of at least one material selected from the group consisting of a SiO₂ layer and a SiON layer.

5. The semiconductor device as claimed in claim 3, wherein the gate comprises a polysilicon layer doped with boron.

6. The semiconductor device as claimed in claim 1, wherein the composite further contains N.

7. The semiconductor device as claimed in claim 6, wherein the number of layers containing the second element within the gate dielectric layer is greater than the number of layers containing the first element.

8. The semiconductor device as claimed in claim 7, wherein the diffusion barrier consists essentially of at least one material selected from the group consisting of a SiO₂ layer, a HfO₂ layer, a ZrO₂ layer, a silicate oxide layer, a SiON layer, a HfON layer, a ZrON layer, and a silicate oxynitride layer.

9. The semiconductor device as claimed in claim 7, further comprising:
a buffer layer interposed between the semiconductor substrate and the gate dielectric layer, wherein the buffer layer consists essentially of at least one material selected from the group consisting of a SiO₂ layer and a SiON layer.

10. The semiconductor device as claimed in claim 7, wherein the gate comprises a polysilicon layer doped with boron.

11. A semiconductor device, comprising:
a semiconductor substrate having a first region in which an nMOS transistor is formed, and a second region in which a pMOS transistor is formed;
first and second gate dielectric layers formed on the first and second regions of the semiconductor substrate, respectively, each dielectric layer being formed of a composite consisting essentially of a first element and a second element, each of these elements being combined with oxygen, the first element being at least one member of a first group consisting of Al, La, Y, Ga, and In, and the second element being at least one member of a second group consisting of Hf, Zr, and Ti;
a diffusion barrier formed on the second gate dielectric layer of the second region; and
first and second gates formed on the first gate dielectric layer and on the diffusion barrier on the second dielectric layer, respectively.

12. The semiconductor device as claimed in claim 11, wherein the number of layers containing the second element within the first and second gate dielectric layers is greater than the number of layers containing the first element.

13. The semiconductor device as claimed in claim 12, wherein the diffusion barrier consists essentially of at least one material selected from the group consisting of a SiO₂ layer, a HfO₂ layer, a ZrO₂ layer, a silicate oxide layer, a SiON layer, a HfON layer, a ZrON layer, and a silicate oxynitride layer.

14. The semiconductor device as claimed in claim 13, further comprising:
buffer layers interposed between the semiconductor substrate and the first and second gate dielectric layers, wherein the buffer layers consist essentially of at least one material selected from the group consisting of a SiO₂ layer and a SiON layer.

15. The semiconductor device as claimed in claim 13, wherein the second gate comprises a polysilicon layer doped with boron.

16. The semiconductor device as claimed in claim 11, wherein the gate dielectric layer composites further contain N.

17. The semiconductor device as claimed in claim 16, wherein the number of layers containing the second element within each of the first and second gate dielectric layers is greater than the number of layers containing the first element.

18. The semiconductor device as claimed in claim 17, wherein the diffusion barrier consists essentially of at least one material selected from the group consisting of a SiO₂ layer, a HfO₂ layer, a ZrO₂ layer, a silicate oxide layer, a SiON layer, a HfON layer, a ZrON layer, and a silicate oxynitride layer.

19. The semiconductor device as claimed in claim 17, further comprising:
buffer layers interposed between the semiconductor substrate and the first and second gate dielectric layers, wherein the buffer layers consist essentially of at least one material selected from the group consisting of a SiO₂ layer and a SiON layer.

20. The semiconductor device as claimed in claim 17, wherein the second gate comprises a polysilicon layer doped with boron.

21. A method for fabricating a semiconductor device, comprising the steps of:
forming a gate dielectric layer on a semiconductor substrate of a composite consisting essentially of a first element and a second element, each of these elements being combined with oxygen, the first element being at least one member of a first group consisting of Al, La, Y, Ga, and In, and the second element being at least one member of a second group consisting of Hf, Zr, and Ti;
forming a diffusion barrier on the gate dielectric layer; and
forming a gate on the diffusion barrier.

22. The method as claimed in claim 21, wherein the second element is formed such that the number of layers containing the second element within the gate dielectric layer is greater than the number of layers containing the first element.

23. The method as claimed in claim 21, wherein the gate dielectric layer is formed using an atomic layer deposition method.

24. The method as claimed in claim 23, wherein the step of forming the gate dielectric layer includes the sequential sub-steps of:
forming at least one first molecular layer containing the first element and O; and
forming at least one second molecular layer containing the second element and O.

25. The method as claimed in claim 24, wherein the sub-step of forming the first molecular layer includes the sequential steps of:
supplying a deposition source of the first element into a reaction chamber under reaction conditions where the semiconductor substrate is located;
performing a first purge;
supplying an oxidation source into the reaction chamber under reaction conditions; and
performing a second purge; and further wherein
the sub-step of forming the second molecular layer includes the sequential steps of:
supplying a deposition source of the second element into the reaction chamber under reaction conditions where the semiconductor substrate is located;
performing a third purge;
supplying an oxidation source into the reaction chamber under reaction conditions; and
performing a fourth purge.

26. The method as claimed in claim 24, wherein the step of forming the second molecular layer is repeated at least once after the initial formation of the second molecular layer.

27. The method as claimed in claim 25, further comprising the steps of:
supplying a source containing N into the reaction chamber under reaction conditions after performing any one of the first, second, third, and fourth purges; and
performing a purge of the source containing N before any subsequent step.

28. The method as claimed in claim 21, wherein the diffusion barrier consists essentially of at least one material selected from the group consisting of a SiO₂ layer, a HfO₂ layer, a ZrO₂ layer, a silicate oxide layer, a SiON layer, a HfON layer, a ZrON layer, and a silicate oxynitride layer.

29. The method as claimed in claim 28, wherein the gate is formed of a polysilicon layer doped with boron.

30. The method as claimed in claim 24, further comprising the step of:
forming a buffer layer consisting essentially of at least one material selected from the group consisting of a SiO₂ layer and a SiON layer on the semiconductor substrate before forming the gate dielectric layer.

31. A semiconductor device made by the steps of:
forming a gate dielectric layer on a semiconductor substrate of a composite consisting essentially of a first element and a second element, each of these elements being combined with oxygen, the first element being at least one member of a first group consisting of Al, La, Y, Ga, and In, and the second element being at least one member of a second group consisting of Hf, Zr, and Ti;
forming a diffusion barrier on the gate dielectric layer; and
forming a gate on the diffusion barrier.

32. A semiconductor device according to claim 31 further wherein the second element is formed such that the number of layers containing the second element within the gate dielectric layer is greater than the number of layers containing the first element.

33. A semiconductor device according to claim 31 further wherein the gate dielectric layer is formed using an atomic layer deposition method.

34. A semiconductor device according to claim 33 further wherein the step of forming the gate dielectric layer includes the sequential sub-steps of:
forming at least one first molecular layer containing the first element and O; and
forming at least one second molecular layer containing the second element and O.

35. A semiconductor device according to claim 34 further wherein the sub-step of forming the first molecular layer includes the sequential steps of:
supplying a deposition source of the first element into a reaction chamber under reaction conditions where the semiconductor substrate is located;
performing a first purge;
supplying an oxidation source into the reaction chamber under reaction conditions; and
performing a second purge; and further wherein
the sub-step of forming the second molecular layer includes the sequential steps of:
supplying a deposition source of the second element into the reaction chamber under reaction conditions where the semiconductor substrate is located;
performing a third purge;
supplying an oxidation source into the reaction chamber under reaction conditions; and
performing a fourth purge.

36. A semiconductor device according to claim 34 further wherein the step of forming the second molecular layer is repeated at least once after the initial formation of the second molecular layer.

37. A semiconductor device according to claim 35 further comprising the steps of:
supplying a source containing N into the reaction chamber under reaction conditions after performing any one of the first, second, third, and fourth purges; and
performing a purge of the source containing N before any subsequent step.

38. A semiconductor device according to claim 31 further wherein the diffusion barrier consists essentially of at least one material selected from the group consisting of a SiO₂ layer, a HfO₂ layer, a ZrO₂ layer, a silicate oxide layer, a SiON layer, a HfON layer, a ZrON layer, and a silicate oxynitride layer.

39. A semiconductor device according to claim 38 further wherein the gate is formed of a polysilicon layer doped with boron.

40. A semiconductor device according to claim 31 further comprising the step of:
forming a buffer layer consisting essentially of at least one material selected from the group consisting of a SiO₂ layer and a SiON layer on the semiconductor substrate before forming the gate dielectric layer.
